(19) United States
(12) Patent Application Publication
(10) Pub. No.: US 2016/0050753 A1
(43) Pub. Date: Feb. 18, 2016

(54) INTERPOSER AND FABRICATION METHOD THEREOF

(71) Applicant: Siliconware Precision Industries Co., Ltd., Taichung (TW)

(72) Inventors: Wen-Ching Chan, Taichung (TW); Chien-Min Lin, Taichung (TW); Po-Yi Wu, Taichung (TW); Chun-Hung Lu, Taichung (TW)

(21) Appl. No.: 14/739,026

(22) Filed: Jun. 15, 2015

(30) Foreign Application Priority Data
Aug. 13, 2014 (TW) 103127721

(51) Int. Cl. H05K 1/11; H05K 3/42; H01L 21/48; H01L 23/498; H01L 23/31

(52) U.S. Cl. CPC H05K 1/112; H01L 23/49827; H01L 23/49822; H01L 23/49838; H01L 23/3171; H01L 21/4857; H01L 21/486; H05K 3/423

(57) ABSTRACT

A method for fabricating an interposer is provided, which includes the steps of: providing a substrate body having opposite first and second sides and a plurality of conductive through holes communicating the first and second sides; forming an insulating layer on the first side of the substrate body, wherein the insulating layer has a plurality of openings correspondingly exposing the conductive through holes; and forming a plurality of conductive pads in the openings of the insulating layer, wherein the conductive pads are electrically connected to the corresponding conductive through holes, thereby dispensing with the conventional wet etching process and hence preventing an undercut structure from being formed under the conductive pads.

### BACKGROUND OF THE INVENTION

1. Field of the Invention

The present invention relates to interposers, and more particularly, to an interposer applied in a semiconductor package and a fabrication method thereof.

2. Description of Related Art

Along with the rapid development of electronic industries, electronic products are developed toward the trend of multi-function and high performance. Accordingly, there have been developed various types of flip-chip packaging modules such as chip scale packages (CSPs), direct chip attached (DCA) packages and multi-chip modules (MCM), and 3D IC chip stacking technologies.

FIG. 1 is a schematic cross-sectional view of a 3D chip stack package. Referring to FIG. 1, a silicon interposer 1 is provided. The silicon interposer 1 has a chip mounting side 10b having an RDL (redistribution layer) structure 11 formed thereon, an external connection side 10a opposite to the chip mounting side 10b, and a plurality of through silicon vias (TSVs) 100 communicating the chip mounting side 10b and the external connection side 10a. A semiconductor chip 6 having a plurality of electrode pads 60 is disposed on the chip mounting side 10b of the silicon interposer 1 and the electrode pads 60 are electrically connected to the RLD structure 11 through a plurality of solder bumps 61. The electrode pads 60 have a small pitch therebetween. Further, an underfill 62 is formed between the semiconductor chip 6 and the RDL structure 11 of the silicon interposer 1 for encapsulating the solder bumps 61. Furthermore, a packaging substrate 7 having a plurality of bonding pads 70 is disposed on the external connection side 10a of the silicon interposer 1 and the bonding pads 70 are electrically connected to the TSVs 100 through a plurality of conductive elements 18 such as bumps. The bonding pads 70 of the packaging substrate 7 have a large pitch therebetween. In addition, an encapsulant 8 is formed on the packaging substrate 7 for encapsulating the semiconductor chip 6.

FIGS. 1A to 1F are schematic cross-sectional views showing a method for fabricating the external connection side 10a of the silicon interposer 1 according to the prior art.

Referring to FIG. 1A, a silicon substrate body 10 is provided. The silicon substrate body 10 has an external connection side 10a, a chip mounting side 10b opposite to the external connection side 10a, and a plurality of TSVs 100 communicating the external connection side 10a and the chip mounting side 10b. Further, an RDL structure 11 is formed on the chip mounting side 10b of the silicon substrate body 10 and electrically connected to the TSVs 100, and a passivation layer 12 is formed on the external connection side 10a of the silicon substrate body 10.

Referring to FIG. 1B, a first conductive layer 14, i.e., a seed layer, is formed on the passivation layer 12 and the TSVs 100.

Referring to FIG. 1C, a plurality of conductive pads 16 are formed on the TSVs 100 through a patterned resist layer (not shown) by electroplating. Then, the resist layer is removed. Generally, the line width/height (for example, the thickness d of the conductive pad 16 of FIG. 1C′) of the silicon interposer 1 is below 3 um. The thickness of the seed layer, i.e., the thickness t of the first conductive layer 14 of FIG. 1C′, is below 1 um.

Referring to FIG. 1D, the first conductive layer 14 under the resist layer is removed by wet etching, and the conductive pads 16 are electrically connected to the TSVs 100.

Referring to FIG. 1E, an insulating layer 13 is formed on the passviation layer 12 and the conductive pads 16 and has a plurality of openings 130 correspondingly exposing the conductive pads 16.

Referring to FIG. 1F, a second conductive layer 14′ is formed on the insulating layer 13 and the conductive pads 16. Subsequently, a plurality of conductive elements 18 made of such as a solder material are formed on the conductive pads 16 through a patterned resist layer 17 by electroplating.

Referring to FIG. 1G the resist layer 17 and the second conductive layer 14′ under the resist layer 17 are removed.

However, in the above-described method of the silicon interposer 1, when the first conductive layer 14 under the resist layer is removed by wet etching, since the wet etching is an isotropic etching, even if the etching solution is used for selective etching, the first conductive layer 14 under the conductive pads 16 will be corroded, thus resulting in an undercut structure. Referring to FIG. 1C′, the conductive layer 14 under the conductive pad 16 has an undercut width r. As such, it becomes difficult for the conductive pads 16 to be vertically disposed on the corresponding TSVs 100.

Further, during the wet etching process, the conductive pads 16 are also partially corroded and consequently the width thereof is less than a predetermined width L (as shown in FIG. 1C′), thus adversely affecting the electrical performance of the overall structure.

Therefore, there is a need to provide an interposer and a fabrication method thereof so as to overcome the above-described drawbacks.

### SUMMARY OF THE INVENTION

In view of the above-described drawbacks, the present invention provides an interposer, which comprises: a substrate body having opposite first and second sides and a plurality of conductive through holes communicating the first and second sides; an insulating layer formed on the first side of the substrate body and having a plurality of openings correspondingly exposing the conductive through holes; a plurality of conductive pads formed in the openings of the insulating layer and electrically connected to the corresponding conductive through holes; and a conductive layer formed between the openings and the corresponding conductive pads.

The present invention further provides a method for fabricating an interposer, which comprises the steps of: providing a substrate body having opposite first and second sides and a plurality of conductive through holes communicating the first and second sides; forming an insulating layer on the first side of the substrate body, wherein the insulating layer has a plurality of openings correspondingly exposing the conductive through holes; and forming a plurality of conductive pads in the openings of the insulating layer, wherein the conductive pads are electrically connected to the corresponding conductive through holes.

In the above-described method, the conductive pads can be formed by electroplating.

In the above-described method, forming the conductive pads can comprise: forming a conductive layer on the insulating layer and in the openings; forming a conductive material on the conductive layer on the insulating layer and in the openings; and removing the conductive layer on the insulating layer and the conductive material on the conductive layer on the insulating layer, the remaining conductive material in the openings forming the conductive pads. Therefore, the conductive layer is formed between the conductive through holes and the corresponding conductive pads and between the openings and the corresponding conductive pads.

In the above-described interposer and method, the substrate body can be a semiconductor plate.

In the above-described interposer and method, the first side of the substrate body can have at least a passivation layer formed thereon.

In the above-described interposer and method, the second side of the substrate body can have a circuit structure formed thereon. Further, the conductive through holes can be electrically connected to the circuit structure.

In the above-described interposer and method, the surface of the conductive pads can be flush with the surface of the insulating layer.

In the above-described interposer and method, a plurality of conductive elements can be formed on the conductive pads.

According to the present invention, the insulating layer is first formed on the first side of the substrate body and then the conductive pads are formed in the openings of the insulating layer. As such, during formation of the conductive pads, the present invention eliminates the need to remove a resist layer and perform a wet etching process as required in the prior art, thereby reducing the material cost, simplifying the fabrication process and increasing the product yield.

Further, by dispensing with the wet etching process, the present invention prevents an undercut structure from being formed between the conductive pads and the conductive layer and hence avoids the conventional drawbacks caused by the undercut structure.

### BRIEF DESCRIPTION OF DRAWINGS

FIG. 1 is a schematic cross-sectional view of a conventional silicon interposer;

FIGS. 1A to 1G are schematic cross-sectional views showing a method for fabricating a silicon interposer according to the prior art, wherein FIG. 1C′ is a partially enlarged view of FIG. 1C; and

FIGS. 2A to 2G are schematic cross-sectional views showing a method for fabricating an interposer according to the present invention.

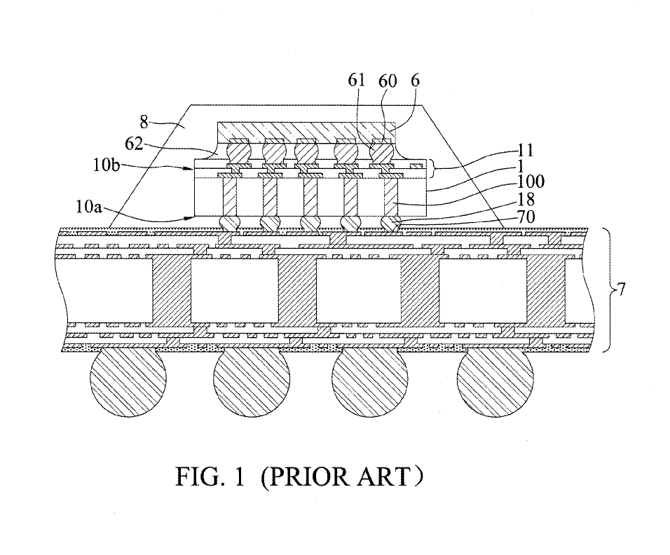

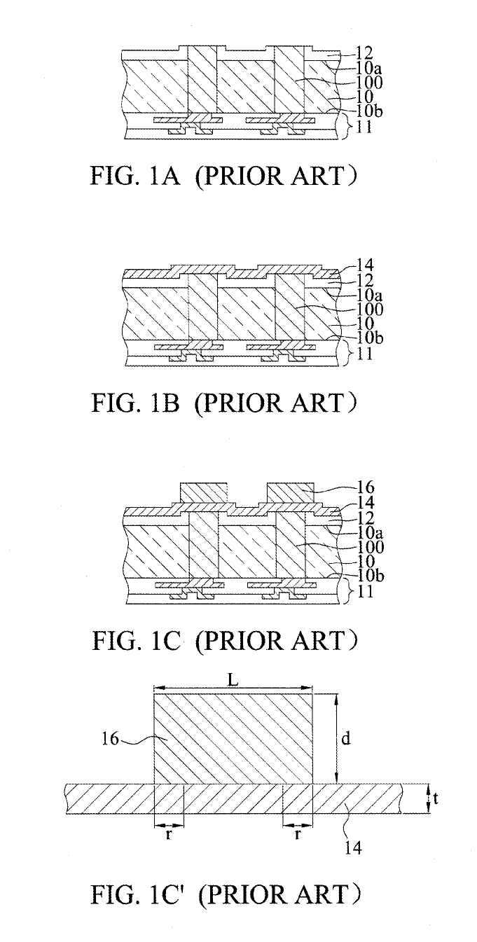

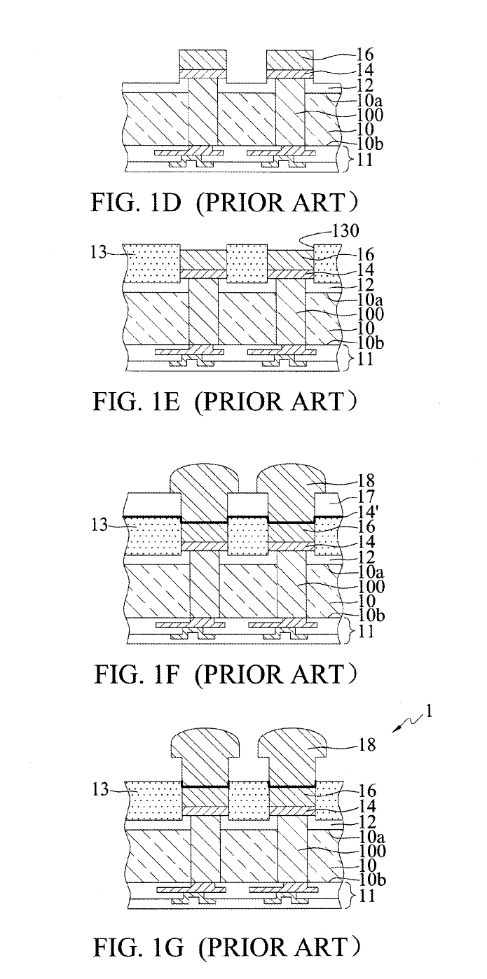

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “on”, “a” etc. are merely for illustrative purposes and should not be construed to limit the scope of the present invention.

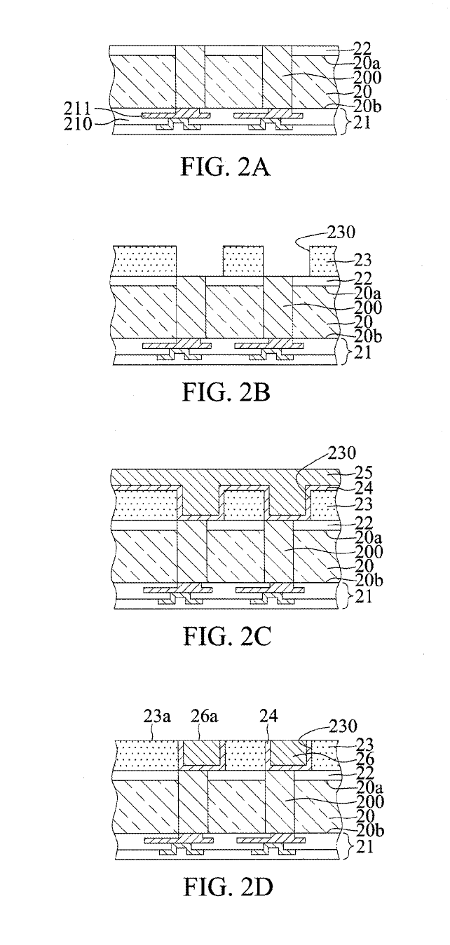

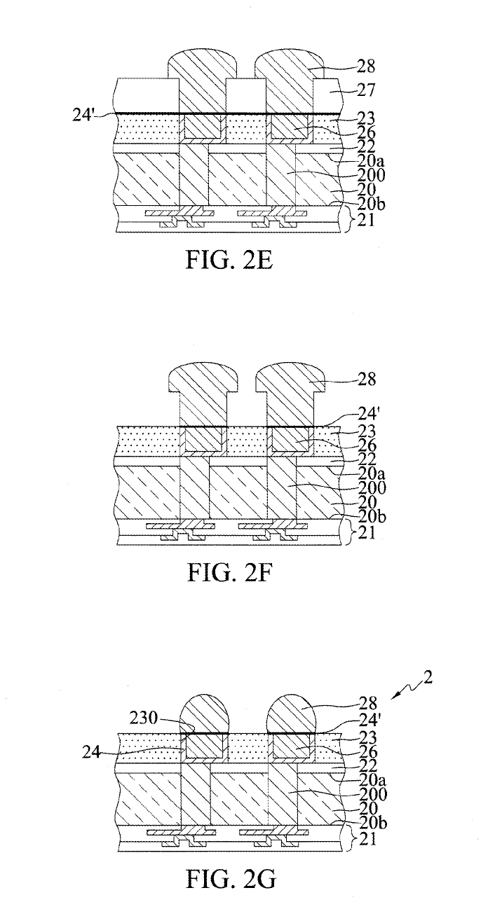

FIGS. 2A to 2G are schematic cross-sectional views showing a method for fabricating an interposer 2 according to the present invention.

Referring to FIG. 2A, a substrate body 20 having a first side 20a (i.e., an external connection side) and a second side 20b (i.e., a chip mounting side) opposite to the first side 20a is provided. The substrate body 20 is a semiconductor plate. A plurality of conductive through holes 200 are formed in the substrate body 20 and communicating the first side 20a and the second side 20b.

In the present embodiment, the substrate body 20 is a silicon-containing plate, for example, a silicon wafer or a glass substrate. Through an RDL process, a circuit structure 21 is already formed on the second side 20b of the substrate body 20 and electrically connected to the conductive through holes 200. The circuit structure 21 has at least a dielectric layer 210 and a circuit layer 211 formed on the dielectric layer 210 and electrically connected to the conductive through holes 200.

Further, a passivation layer 22 is formed on the first side 20a of the substrate body 20. The passivation layer 22 is an oxide layer such as a silicon dioxide layer, or a nitride layer such as a silicon nitride layer.

Referring to FIG. 2B, an insulating layer 23 is formed on the passivation layer 22 on the first side 20a of the substrate body 20 and has a plurality of openings 230 correspondingly exposing the conductive through holes 200.

In the present embodiment, the insulating layer 22 is an oxide layer such as a silicon dioxide layer, or a nitride layer such as a silicon nitride layer.

Referring to FIG. 2C, a first conductive layer 24 is formed on the insulating layer 23 and in the openings 230 of the insulating layer 23. Then, a conductive material 25 such as copper is formed on the first conductive layer 24 on the insulating layer 23 and in the openings 230.

In the present embodiment, an RDL process is performed, and the conductive material 25 is formed through the first conductive layer 24 by electroplating.

Referring to FIG. 2D, a CMP (chemical mechanical polishing) process is performed to remove the first conductive layer 24 on the insulating layer 23 and the conductive material 25 on the first conductive layer 24 on the insulating layer 23. As such, the remaining conductive material 25 in the openings 230 forms a plurality of conductive pads 26. The conductive pads 26 are electrically connected to the corresponding conductive through holes 200.

In the present embodiment, the surface 26a of the conductive pads 26 is flush with the surface 23a of the insulating layer 23.

Referring to FIG. 2E, a second conductive layer 24′ is formed on the insulating layer 23 and the conductive pads 26. Subsequently, a plurality of conductive elements 28 made of such as a solder material are formed on the conductive pads 26 through a patterned resist layer 27 by electroplating.

Referring to FIG. 2F, the resist layer 27 and the second conductive layer 24′ under the resist layer 27 are removed.

Referring to FIG. 2G the conductive elements 28 are reflowed.

According to the present invention, the insulating layer 23 is first formed on the first side 20a of the substrate body 20 and then the conductive material 25 is formed on the first side 20a of the substrate body 20 and excess portions of the conductive material 25 are removed so as to form a plurality of conductive pads 26 in the openings of the insulating layer 23. As such, during formation of the conductive pads 26, the present invention eliminates the need to remove a resist layer and perform a wet etching process as required in the prior art, thereby reducing the material cost, simplifying the fabrication process and increasing the product yield.

Further, by dispensing with the wet etching process, the present invention prevents an undercut structure from being formed between the conductive pads 26 and the conductive layer 24 and hence avoids the conventional drawbacks caused by the undercut structure.

The present invention further provides an interposer 2, which has: a substrate body 20 having opposite first and second sides 20a, 20b and a plurality of conductive through holes 200 communicating the first and second sides 20a, 20b; an insulating layer 23 formed on the first side 20a of the substrate body 20 and having a plurality of openings 230 correspondingly exposing the conductive through holes 200; a plurality of conductive pads 26 formed in the openings 230 of the insulating layer 23 and electrically connected to the corresponding conductive through holes 200; and a conductive layer 24 formed between the openings 230 and the corresponding conductive pads 26.

In an embodiment, a circuit structure 21 is formed on the second side 20b of the substrate body 20. Further, the conductive through holes 200 are electrically connected to the circuit structure 21.

In an embodiment, the substrate body 20 is a semiconductor plate.

In an embodiment, a passivation layer 22 is formed on the first side 20a of the substrate body 20.

In an embodiment, the surface 26a of the conductive pads 26 is flush with the surface 23a of the insulating layer 23.

In an embodiment, the conductive layer 24 is formed between the conductive through holes 200 and the corresponding conductive pads 26.

In an embodiment, the interposer 2 further has a plurality of conductive elements 28 formed on the conductive pads 26.

Therefore, by first forming the insulating layer and then forming the conductive pads, the present invention dispenses with the wet etching process so as to reduce the material cost, simplify the fabrication process and increase the product yield. Also, the present invention prevents an undercut structure from being formed under the conductive pads.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. An interposer, comprising:
a substrate body having opposite first and second sides and a plurality of conductive through holes communicating the first and second sides;
an insulating layer formed on the first side of the substrate body and having a plurality of openings correspondingly exposing the conductive through holes;
a plurality of conductive pads formed in the openings of the insulating layer and electrically connected to the corresponding conductive through holes; and
a conductive layer formed between the openings and the corresponding conductive pads.

2. The interposer of claim 1, wherein the substrate body is a semiconductor plate.

3. The interposer of claim 1, wherein at least a passivation layer is formed on the first side of the substrate body.

4. The interposer of claim 1, wherein a circuit structure is formed on the second side of the substrate body.

5. The interposer of claim 4, wherein the conductive through holes are electrically connected to the circuit structure.

6. The interposer of claim 1, wherein the surface of the conductive pads is flush with a surface of the insulating layer.

7. The interposer of claim 1, wherein the conductive layer is formed between the conductive through holes and the corresponding conductive pads.

8. The interposer of claim 1, further comprising a plurality of conductive elements formed on the conductive pads.

9. A method for fabricating an interposer, comprising the steps of:
providing a substrate body having opposite first and second sides and a plurality of conductive through holes communicating the first and second sides;
forming an insulating layer on the first side of the substrate body, wherein the insulating layer has a plurality of openings correspondingly exposing the conductive through holes; and
forming a plurality of conductive pads in the openings of the insulating layer, wherein the conductive pads are electrically connected to the corresponding conductive through holes.

10. The method of claim 9, wherein the substrate body is a semiconductor plate.

11. The method of claim 9, wherein the first side of the substrate body has at least a passivation layer formed thereon.

12. The method of claim 9, wherein the second side of the substrate body has a circuit structure formed thereon.

13. The method of claim 12, wherein the conductive through holes are electrically connected to the circuit structure.

14. The method of claim 9, wherein the surface of the conductive pads is flush with a surface of the insulating layer.

15. The method of claim 9, wherein the conductive pads are formed by electroplating.

16. The method of claim 9, wherein forming the conductive pads comprises:
forming a conductive layer on the insulating layer and in the openings;
forming a conductive material on the conductive layer on the insulating layer and in the openings; and
removing the conductive layer on the insulating layer and the conductive material on the conductive layer on the insulating layer, so as for the remaining conductive material in the openings to form the conductive pads.

17. The method of claim 16, wherein the conductive layer is formed between the conductive through holes and the corresponding conductive pads and between the openings and the corresponding conductive pads.

18. The method of claim 9, further comprising forming a plurality of conductive elements on the conductive pads.
